(19) United States
(12) Patent Application Publication
(10) Pub. No.: US 2024/0162128 A1
(43) Pub. Date: May 16, 2024

(54) METHODS OF FABRICATING SEMICONDUCTOR PACKAGE

(71) Applicant: LBSEMICON CO., LTD., Pyeongtaek-si Gyeonggi-do (KR)

(72) Inventor: Gi Jo JUNG, Pyeongtaek-si Gyeonggi-do (KR)

(73) Assignee: LBSEMICON CO., LTD., Pyeongtaek-si Gyeonggi-do (KR)

(21) Appl. No.: 18/477,767

(22) Filed: Sep. 29, 2023

(30) Foreign Application Priority Data
Nov. 16, 2022 (KR) 10-2022-0153987

(51) Int. Cl. H01L 23/498; H01L 21/48; H01L 21/60

(52) U.S. Cl. CPC H01L 23/49811; H01L 21/4853; H01L 21/60; H01L 2021/60232

(57) ABSTRACT

A method of fabricating a semiconductor package is provided. The method may include: forming a first insulating film on a substrate which is at least partially provided with a semiconductor chip; forming a redistribution layer on the first insulating film; forming a solder crack control part, capable of controlling crack defects of a solder ball, on at least a portion of the redistribution layer; forming a second insulating layer on the redistribution layer and at least a portion of the first insulating film to expose a portion of the redistribution layer and the solder crack control part; and forming a solder ball on the redistribution layer exposed and the solder crack control part, wherein a top surface level of the solder crack control part may be formed to be relatively higher than a top surface level of the second insulating film.

### CROSS-REFERENCE TO RELATED PATENT APPLICATION

This application claims priority under 35 U.S.C. § 119(a) to Korean Patent Application No. 10-2022-0153987, filed on Nov. 16, 2022, in the Korean Intellectual Property Office, the disclosure of which is incorporated herein in its entirety by reference.

### BACKGROUND OF THE INVENTION

### 1. Field of the Invention

The following description relates to a method of fabricating a semiconductor package, and more specifically, to a fan-out wafer level package (FOWLP) or wafer-level chip size package (WLCSP).

### 2. Description of the Related Art

The current trend in the electronics industry is to manufacture lightweight, compact, high-speed, multifunctional, high-performance, and cost-effective products with high reliability. One of the important technologies that enable the realization of such product goals is package technologies and one of the packages developed recently is a chip scale package (CSP). The chip scale package is a small semiconductor package having a size of a semiconductor chip. However, while CSP has an absolute advantage in terms of size, it still has several disadvantages compared to traditional plastic packages. One of the disadvantages is the difficulty in ensuring reliability, and another is that the manufacturing equipment and raw materials required for CSP production are extensive, leading to high manufacturing costs and decreased price competitiveness. An alternative solution to address these issues is the emergence of wafer-level chip scale packages. In other words, when semiconductor wafers are manufactured through the conventional wafer fabrication process, individual chips are separated from the wafer and then go through a package assembly process. The package assembly process is entirely separate from the wafer fabrication process and requires different equipment and raw materials. However, at the wafer level, it is possible to manufacture a complete package without separating individual chips from the wafer. In addition, existing wafer manufacturing equipment and processes can be used for the equipment and processes used to fabricate the package. This also means that the use of additional raw materials required to manufacture the package can be minimized.

In the case of a wafer-level package, a fan-in wafer-level package that typically forms terminals and wiring on the inside of the chip has been developed.

In the traditional fan-in wafer-level packaging process, as the size of the chip decreases, the size of solder balls and the pitch between solder balls must also decrease. However, excessively small solder ball sizes may lead to a decrease in bonding strength, and too small a pitch between solder balls may result in contact defects such as solder ball bridging. Additionally, there is inconvenience in having to change the layout of wiring and other components as the size of the chip changes.

To address these inconveniences, an improved fan-out wafer-level package allows for the placement of input/output (I/O) terminals and wiring in the outer part of a semiconductor chip, known as an epoxy mold compound (EMC) area. This reduces the defects caused by the aforementioned solder ball size and pitch issues and enables the use of standardized ball layouts even when the size of the semiconductor chip changes. Furthermore, it allows for implementation of system-in-package, which enables multiple chips to be mounted in a single package, and has the advantage of packaging chips with numerous I/O terminals.

### SUMMARY OF THE INVENTION

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

In the conventional method, when solder balls are attached to semiconductor chip pads as described above, since the solder balls are placed directly on a metal pad, there is an issue where applying pressure beyond the standard strength may lead to the occurrence of cracks on the chip pad, resulting in an open circuit in the terminal.

The present invention aims to solve various problems including the problems described above. An object of the present invention is to provide a semiconductor package and a method of fabricating the same, which enhances solder bonding characteristics by minimizing cracks in a pad where a solder ball is bonded during the fabrication of a fan-out wafer-level package. However, the above object is illustrative only, and does not limit the scope of the present invention.

According to one embodiment of the present invention, there is provided a method of fabricating a fan-out wafer-level semiconductor package. The method may include: forming a first insulating film on a substrate which is at least partially provided with a semiconductor chip; forming a redistribution layer on the first insulating film; forming a solder crack control part, capable of controlling crack defects of a solder ball, on at least a portion of the redistribution layer; forming a second insulating layer on the redistribution layer and at least a portion of the first insulating film to expose a portion of the redistribution layer and the solder crack control part; and forming a solder ball on the redistribution layer exposed and the solder crack control part, wherein a top surface level of the solder crack control part may be formed to be relatively higher than a top surface level of the second insulating film.

Additionally, according to the present invention, the solder crack control part may be formed with a thickness twice or more a thickness of the second insulating film formed on the redistribution layer.

Also, according to the present invention, the forming of the redistribution layer may include forming a redistribution seed layer on the first insulating film; forming a space where the redistribution layer is to be formed by applying a photoresist film on the seed layer, followed by sequentially performing an exposure process and a development process; forming the redistribution layer on the redistribution seed layer exposed; and removing the photoresist film after forming the redistribution layer.

In addition, according to the present invention, the forming of the solder crack control part may include forming a space where the solder crack control part is to be formed by applying a photoresist film on the redistribution layer, followed by sequentially performing an exposure process and a development process; forming the solder crack control part on the exposed redistribution layer; and removing the photoresist film after forming the solder crack control part.

Moreover, according to the present invention, the method may include, after removing the photoresist film, removing at least a portion of the exposed redistribution seed layer.

In addition, according to the present invention, the forming of the second insulating film may include coating the second insulating film on the first insulating film exposed and at least a portion of the redistribution layer by using a mask.

Furthermore, according to the present invention, the forming of the second insulating film may include forming a space where the second insulating film is to be formed by applying a photoresist film on the redistribution layer and at least a portion of the solder crack control part, followed by sequentially performing an exposure process and a development process; forming the second insulating layer on the exposed first insulating film and redistribution layer; and removing the photoresist film after forming the second insulating film.

According to another embodiment of the present invention, there is provided a method of fabricating a fan-out wafer-level semiconductor package. The method may include: forming a first insulating film on a substrate which is at least partially provided with a semiconductor chip; forming a redistribution layer on the first insulating film; forming a second insulating layer on the redistribution layer and the first insulating film except for a space where an under bump metal (UBM) pattern is to be formed in a portion of the redistribution layer; forming the UBM pattern on the redistribution layer exposed; forming a solder crack control part, capable of controlling crack defects of a solder ball, on at least a portion of the UBM; and forming a solder ball on the UBM pattern exposed and the solder crack control part, wherein a top surface level of the solder crack control part may be formed to be relatively higher than a top surface level of the UBM pattern.

Additionally, according to the present invention, the solder crack control part may be formed with a thickness twice or more a thickness of the UBM pattern formed on the second insulating film.

In addition, according to the present invention, the forming of the solder crack control part may include forming a space where the solder crack control part is to be formed by applying a photoresist film on the redistribution layer, followed by sequentially performing an exposure process and a development process; forming the solder crack control part on the exposed UBM pattern; and removing the photoresist film after forming the solder crack control part.

Also, according to the present invention, the forming of the redistribution layer may include forming a redistribution seed layer on the first insulating film; forming a space where the redistribution layer is to be formed by applying a photoresist film on the seed layer, followed by sequentially performing an exposure process and a development process; forming the redistribution layer on the redistribution seed layer exposed; removing the photoresist film after forming the redistribution layer; and removing at least a portion of the redistribution seed layer exposed.

Further, according to the present invention, the forming of the second insulating film may include coating the second insulating film on the first insulating film exposed and at least a portion of the redistribution layer by using a mask.

Furthermore, according to the present invention, the forming of the second insulating film may include forming a space where the second insulating film is to be formed by applying a photoresist film on the redistribution layer, followed by sequentially performing an exposure process and a development process; forming the second insulating layer on the exposed first insulating film and redistribution layer; and removing the photoresist film after forming the second insulating film.

According to yet another embodiment of the present invention there is provided a fan-out wafer-level semiconductor package. The semiconductor package may include: a first insulating film formed on a substrate which is partially provided with a semiconductor chip; a redistribution layer formed on the first insulating film; a second insulating film formed on the redistribution layer and the first insulating film exposed; a solder crack control part formed on the redistribution layer exposed; and a solder ball formed on the exposed redistribution layer and the solder crack control part, wherein a top surface level of the solder crack control part may be formed to be relatively higher than a top surface level of the second insulating film.

Additionally, according to the present invention, the solder crack control part may be formed with a thickness twice or more a thickness of the second insulating film formed on the redistribution layer.

In addition, according to the present invention, the package may further include a UBM pattern interposed between the solder crack control part and the redistribution layer, and the exposed redistribution layer may be enclosed by the UBM pattern.

In addition, according to the present invention, the solder ball may be formed on the UBM pattern and the solder crack control part.

Additionally, according to the present invention, the solder crack control part may be formed with a thickness twice or more a thickness of the UBM pattern formed on the second insulating film.

Additionally, according to the present invention, the solder crack control part may be formed in one of the shapes of a cylinder, a donut, or a polygonal cylinder.

Other features and aspects will be apparent from the following detailed description, the drawings, and the claims.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional view of a semiconductor package according to an embodiment of the present invention.

FIGS. 2 to 9 are cross-sectional views of steps of a process of fabricating the semiconductor package of FIG. 1.

FIG. 10 is a schematic cross-sectional view of a semiconductor package according to an embodiment of the present invention.

FIG. 11 is a schematic cross-sectional view of a semiconductor package according to another embodiment of the present invention.

FIGS. 12 to 13 are top views schematically showing a structure of a solder crack control part according to an embodiment of the present invention.

FIG. 14 is a schematic cross-sectional view of a semiconductor package according to another embodiment of the present invention.

FIG. 15 is a scanning electron microscope (SEM) image that analyzes the structure of a sample in which solder ball cracks occurred in a semiconductor package according to a comparative example of the present invention.

### DETAILED DESCRIPTION OF THE INVENTION

Hereinafter, different preferred embodiments of the present invention will be described in detail with reference to the accompanying drawings.

The embodiments of the present invention are provided to more completely describe the present invention to persons having ordinary knowledge in the art to which the present invention pertains (“those skilled in the art”), the following embodiments may be modified into different forms, and the scope of the present invention is duly not restricted to the following embodiments. On the contrary, these embodiments will be provided to further sufficiently and completely prepare the present disclosure and to perfectly inform those skilled in the art with the spirit of the present invention. In addition, a thickness or size of each layer shown in the figures will be exaggerated for convenience and clarity of the explanation.

The terms used in the present disclosure are used for explaining specific embodiments but not for restricting the present invention. As used in the present disclosure, the singular form may also include the plural form unless otherwise an alternative case is indicated in the context. Further, “comprise” and/or “comprising” in the present disclosure will specify the existence of mentioned shapes, numbers, steps, motions, members, elements and/or the group thereof, however, does not exclude the existence and/or addition of one or more other shapes, numbers, motions, members, elements and/or the groups thereof.

Hereinafter, the embodiments of the present invention will be described with reference to the drawings in which ideal embodiments of the present invention are schematically illustrated. With regard to the drawings, for example, modification of the illustrated shapes may be expected on the basis of manufacturing techniques and/or tolerance. Accordingly, the embodiments of the present inventive spirit should not be construed as limitation to specific morphologies in the section illustrated in the specification, for example, should include a change in morphologies caused during manufacturing.

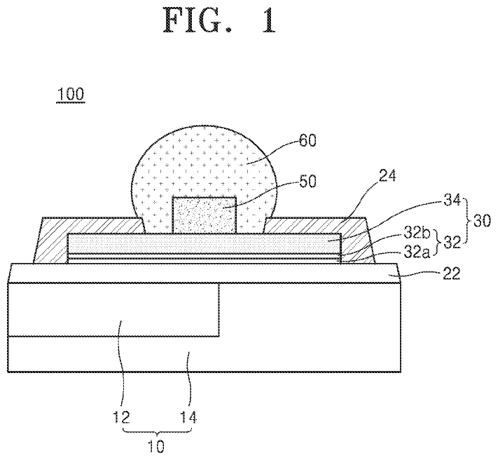

FIG. 1 is a cross-sectional view of a semiconductor package 100 according to an embodiment of the present invention.

First, as shown in FIG. 1, a semiconductor package 100 according to an embodiment of the present invention is a fan-out wafer-level semiconductor package, and may include a first insulating film 22 formed on a substrate 10 which is at least partially provided with a semiconductor chip 12, a redistribution layer 30 formed on the first insulating film 22, a second insulating film 24 formed on the redistribution layer 30 and the exposed first insulating film 22, a solder crack control portion 50 formed on the exposed redistribution layer 30 and configured to control a crack defect of a solder ball 60, and the solder ball 60 formed on the exposed redistribution layer 30 and the solder crack control portion 50.

Here, a top surface level of the solder crack control part 50 may be relatively higher than a top surface level of the second insulating film 24. For example, the solder crack control part 50 may be formed with a thickness twice or more that of the second insulating film 24 formed on the redistribution layer 30. Additionally, the solder crack control part 50 may be formed in one of the shapes of a cylinder, a donut, or a polygonal cylinder.

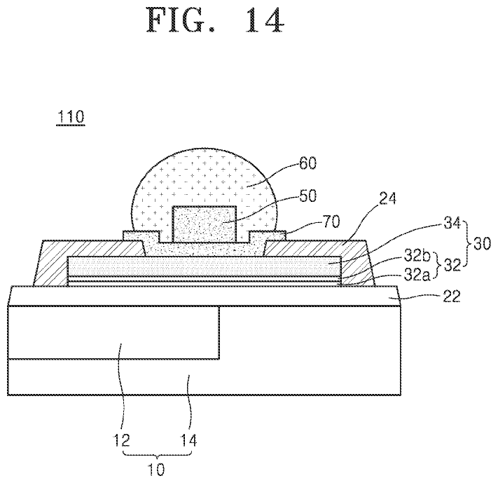

In addition, as shown in FIG. 14, the semiconductor package 100 may further include an under bump metal (UBM) pattern 70 (see FIG. 14) interposed between the solder crack control part 50 and the redistribution layer 30. In this case, the exposed redistribution layer 30 may be enclosed by the UBM pattern 70. When using the UBM pattern 70 in the semiconductor package 100, the solder ball 60 may be formed on the UBM pattern 70 and the solder crack control part 50. The solder crack control part 50 may be formed with a thickness twice or more the thickness of the UBM pattern 70 formed on the second insulating film 24.

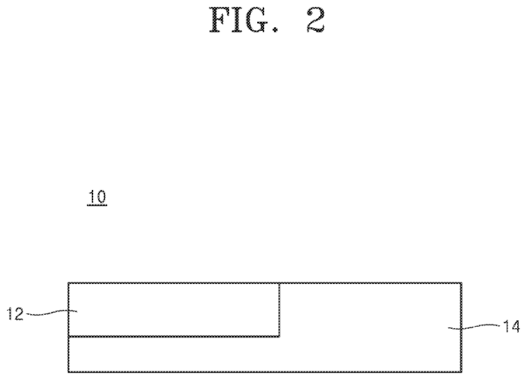

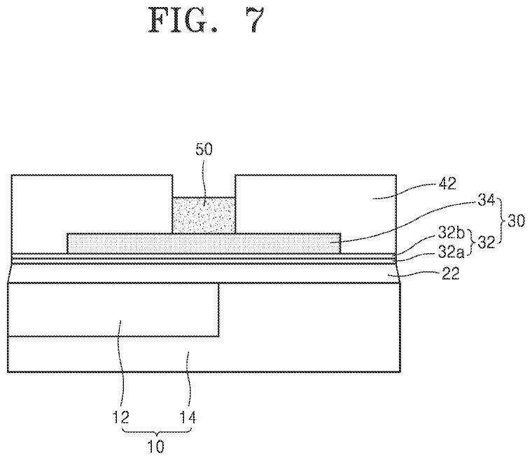

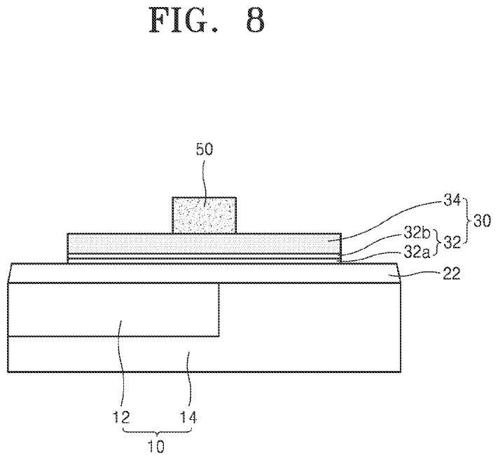

FIGS. 2 to 9 are cross-sectional views of steps of a process of fabricating the semiconductor package of FIG. 1.

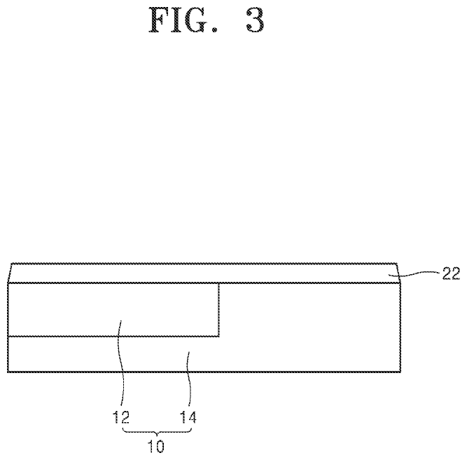

Each step of the process of fabricating the semiconductor package 100 of FIG. 1 is described with reference to FIGS. 2 to 9. First, as shown in FIGS. 2 and 3, the first insulating film 22 may be formed on the substrate 10 which is at least partially provided with the semiconductor chip 12. The substrate 10 may be made of a wafer, a glass substrate, a ceramic substrate, or a similar substrate, and it may include an epoxy mold compound (EMC) area 14 formed in a shape surrounding the sides and bottom of the semiconductor chip 12. The EMC area 14 may be formed in various shapes depending on the size and number of semiconductor chips 12.

The first insulating film 22 may be formed to surround the entire top surface of the semiconductor chip 12 and the EMC area 14, and it may be formed to expose a pad portion of the semiconductor chip 12. For example, the first insulating film 22 may be made of polyimide (PI), and polyimide may be coated on the top surface of the semiconductor chip 12 and the EMC area 14. Subsequently, the first insulating film 22 may be formed by exposing and curing the pad portion (not shown) using alignment and exposure/development processes. However, various processing methods for forming the first insulating film 22 on the substrate 10 may be applied without being limited to this method.

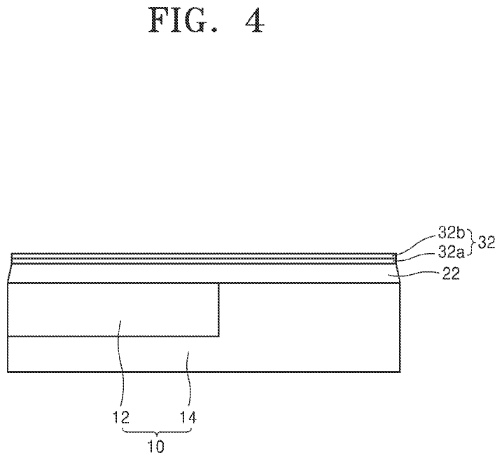

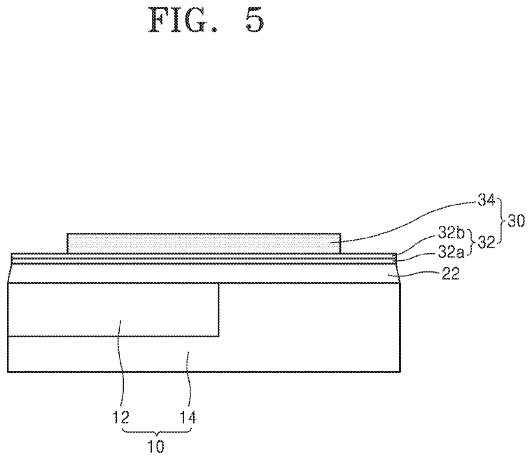

Subsequently, as shown in FIGS. 4 and 5, the redistribution layer 30 may be formed on the first insulating layer 22. The redistribution layer 30 may include a stacked structure of multiple metal layers. For example, referring to the drawings, the redistribution layer 30 may include a first metal layer 32a and a second metal layer 32b that constitute a redistribution seed layer 32, and the redistribution layer 30 may further include a third metal layer 34 formed on the second metal layer 32b. In this case, the second metal layer 32b that constitute the redistribution seed layer 32 and the third metal layer 34 may use the same material. In other words, the redistribution layer 30 may also be formed with a single metal film without the redistribution seed layer (32) and may be configured in various film forms depending on the material used for the redistribution layer 30.

For example, the redistribution layer 30 may be initially formed by stacking various metal layers 32a, 32b, and 34. Specifically, in the redistribution layer 30, the redistribution seed layer 32 may be first formed on the first insulating film 22. The redistribution seed layer 32 may include the first metal layer 32a and the second metal layer 32b.

The first metal layer 32a may be coated on the first insulating film 22, for example, by coating Ti on the first insulating film 22 using a sputtering method to enhance adhesion to the first insulating film 22 and establish electrical connection to the pad portion (not shown) provided on the semiconductor chip 12. Subsequently, as the second metal layer 32b, Cu may be coated on the first metal layer 32a using a sputtering method. Next, the third metal layer 34 may be formed on the second metal layer 32b.

Although not shown in the drawings, after coating the second metal layer 32b, a photoresist film (not shown) may be applied, and alignment, exposure, and development processes may be performed to create a space where the redistribution layer is to be formed, i.e., a space where the third metal layer 34 is coated. Then, Cu may be electroplated as the third metal layer 34 onto the space where the third metal layer 34 is to be formed. After the third metal layer (34) is formed, the photoresist film may be stripped away.

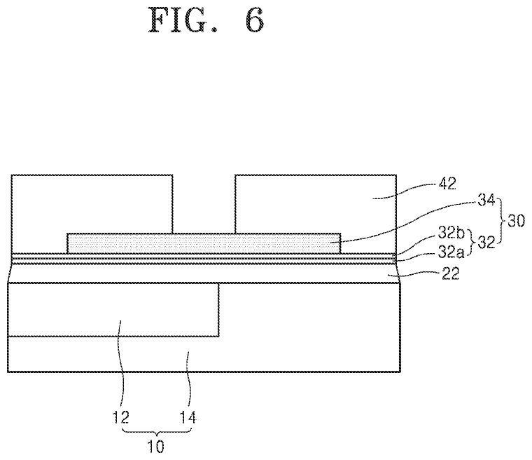

Referring to FIGS. 6 to 8, the solder crack control part 50 may be formed on the redistribution layer 30. To form the solder crack control part 50, a photoresist film 42 may be applied on the redistribution layer 30. Specifically, the photoresist film 42 may be formed on the top surface of the third metal layer 34 and the exposed top surface of the second metal layer 32b. After applying the photoresist film 42, alignment, exposure, and development processes may be performed to create a space where the solder crack control part 50 is to be formed. Subsequently, as the solder crack control part 50, Cu may be electroplated onto the space where the solder crack control part 50 is to be formed, i.e., on the third metal layer 34. After the solder crack control part 50 is formed, the photoresist film 42 may be stripped away. At this point, at least a portion of the redistribution seed layer 32 that is exposed externally may be etched together with the photoresist film 42 and removed. The etching method used here is a known technique, so a detailed description thereof is omitted.

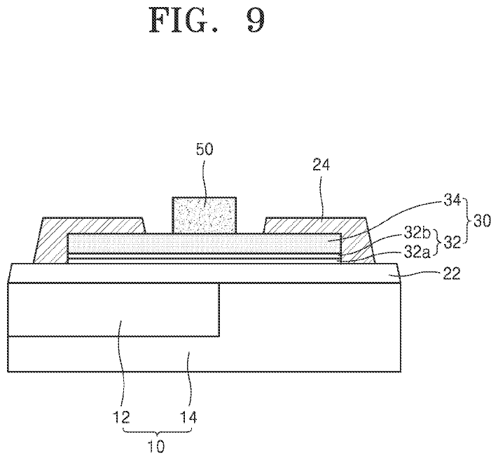

Referring to FIG. 9, the second insulating film 24 may be formed on the first insulating film 22, which is exposed after removing at least a portion of the redistribution seed layer 32, and at least a portion of the redistribution layer 30. The second insulating film 24 may be formed to surround some or all of the top surface and sides of the redistribution layer 30, except for the space where a solder ball (not shown) is to be placed. The second insulating film 24 may use the same material as the first insulating film 22, and, for example, polyimide (PI) may be used.

For example, the second insulating film 24 may be formed by using a mask to coat insulating material on the first insulating film 22 exposed and at least a portion of the redistribution layer 30.

Alternatively, the second insulating film 24 may be formed using the same photoresist method as used for the solder crack control part 50. Specifically, a photoresist film (not shown) may be applied to at least a portion of the redistribution layer 30, followed by coating insulating material in the remaining areas, and alignment, exposure, and development processes may then be performed to create an insulating film pattern. Afterward, the insulating film pattern may be cured to form the second insulating film 24.

As another example, the second insulating film 24 may be coated on the redistribution layer 30 and the first insulating film 22, and a photoresist film may be applied to the space where a solder ball (not shown) is to be formed. Afterwards, alignment, exposure, and development processes may be performed, followed by removing the photoresist film to create an insulating film pattern. A curing process may then be performed to form the second insulating film 24. Various other processes may be used to form the second insulating film 24.

After forming the second insulating film 24, a solder ball 60 may be formed to encapsulate the solder crack control part 50 on the exposed redistribution layer 30. For example, after flux is printed, followed by mounting solder, a reflow process may be performed to form the solder ball 60, as shown in FIG. 1.

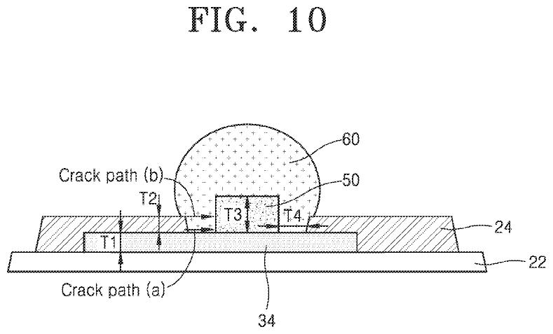

In the following description, further details regarding the solder crack control part 50 will be provided with reference to FIG. 10.

FIG. 10 is a schematic cross-sectional view of a semiconductor package according to an embodiment of the present invention.

Referring to FIG. 10, the top surface level of the solder crack control part 50 may be relatively higher than the top surface level of the second insulating film 24. In this case, the solder crack control part 50 may be formed with a thickness twice or more the thickness of the second insulating film 24 formed on the redistribution layer 30.

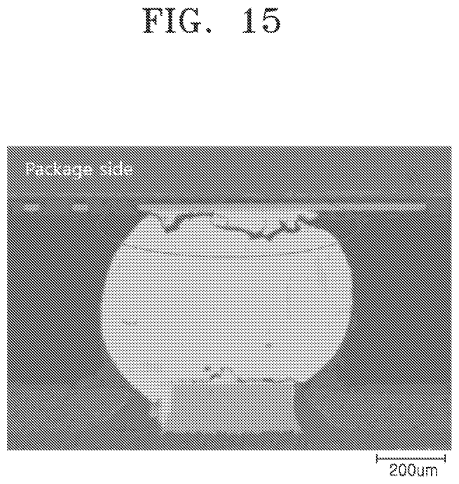

Crack defects in the solder ball 60 occur and propagate along the arrow directions indicated as crack paths (a) and (b) in FIG. 10. Specifically, referring to FIG. 15, in a semiconductor package structure according to a comparative example of the present invention, solder cracks are initially observed near the edge of a pad portion of the redistribution layer and the solder ball. It can be seen that solder cracks propagate along the surface of the copper pad of the printed circuit board PCB from the intermetallic compound layer (IMC layer) formed below the pad portion of the redistribution layer and the wafer-level chip-scale package (WLCSP).

To address this problem, in the present invention, the solder crack control part 50 may be formed to prevent the propagation of solder cracks. Here, the thickness T3 of the solder crack control part 50 may be controlled based on the thickness T1 of the redistribution layer 34, the thickness T2 of the second insulating film 24, and the size of the gap T4 between one side of the solder crack control part 50 and the second insulating film 24.

For example, the thickness T1 of the redistribution layer 34 may be formed to be 7 μm or more, considering the thickness of the Cu IMC layer. The thickness T2 of the second insulating film 24, which is formed on the top surface of the redistribution layer 34 may be 5 μm or more, considering the coverage of the redistribution layer 34. In an area where the redistribution layer 34 is not present, the thickness of the second insulating film 24 may be formed to be 12 μm or more.

Here, considering the propagation path of solder cracks, the solder crack control part 50 may be formed to protrude higher than the top surface of the second insulating film 24. In this case, the thickness T3 of the solder crack control part 50 may be 10 μm or more, which is twice the thickness T2 of the second insulating film 34.

The width of the solder crack control part 50 may be controlled based on the size of an opening in the second insulating film 34. The distance T4 between one side of the solder crack control part 50 and the opening in the second insulating film 34 may be 20 μm or more. The distance T4 between one side of the solder crack control part 50 and the opening in the second insulating film 34 may be set by considering photolithography process conditions.

When the solder ball 60 is mounted on the pad portion of the redistribution layer 34 exposed through the opening of the second insulating film 34, the contact area of the pad portion is increased by the solder crack control part 50, which leads to improved adhesion and enhanced electrical characteristics.

Furthermore, once the size of the solder crack control part 50 is determined, the solder crack control part 50 may be formed in various shapes based on the top surface.

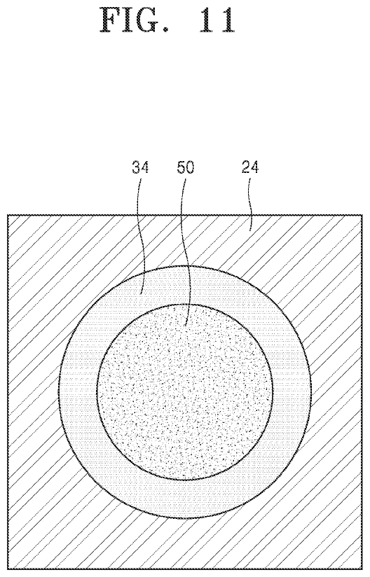

As an example, typically, the solder crack control part 50 is formed in a circular shape, as shown in FIG. 11, and in three dimensions, it may be formed in a cylindrical shape.

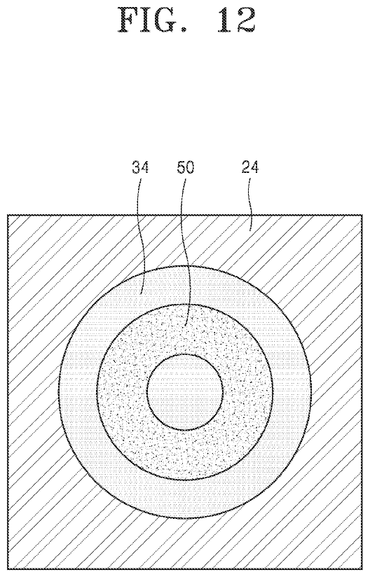

As another example, as shown in FIG. 12, the solder crack control part 50 is formed in a donut shape, and in three dimensions, it may be formed in a cylindrical shape with a through-hole in the center.

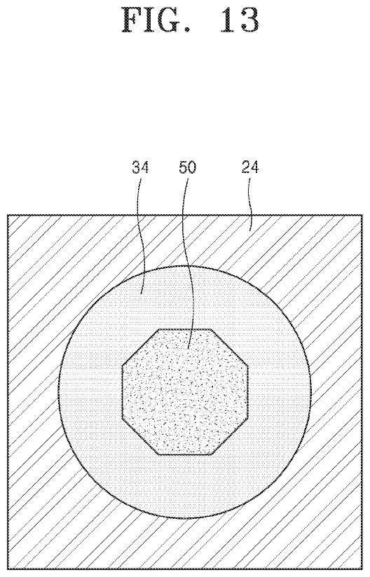

As yet another example, as shown in FIG. 13, it is formed in a polygonal shape, and in three dimensions, it may be formed in a polygonal cylindrical shape or the like.

However, the shape of the solder crack control part 50 is not limited to these examples, and may be any structure that protrudes into the opening of the second insulating film 24 to suppress the propagation of solder crack defects.

FIG. 14 is a schematic cross-sectional view of a semiconductor package according to another embodiment of the present invention.

Referring to FIG. 14, a semiconductor package 110 of the present invention may further include a UBM pattern 70. When further including the UBM pattern 70, a method of fabricating the semiconductor package 110 may be performed as follows.

For example, a step of forming a redistribution layer 30 may be performed in the same way as described in FIGS. 2 to 5. A first insulating film 22 may be formed on a substrate 10 which is at least partially provided with a semiconductor chip 12, and a redistribution seed layer 32 may be formed on the first insulating film 22. After applying a photoresist film on the seed layer 32, the exposure and development processes are sequentially performed to create a space where the redistribution layer 30 is to be formed, and the redistribution layer 30 may be formed on the exposed redistribution seed layer 32. After forming the redistribution layer 30, the photoresist film may be stripped away, and at the same time, at least a portion of the exposed seed layer 32 may be removed together.

Afterwards, a second insulating film 24 may be formed on the redistribution layer 30 and the first insulating film 22 except for a space where a UBM pattern 70 is to be formed in a portion of the redistribution layer 30. Specifically, after coating the second insulating film 22 on the first insulating film 22 exposed and at least a portion of the redistribution layer 30 by using a mask, or after applying a photoresist film to at least some portions of the redistribution layer 30, the exposure and development processes may be performed sequentially to create a space where the second insulating film 24 is to be formed, and then the second insulating film 24 may be formed on the exposed first insulating film 22 and the redistribution layer 30. After forming the second insulating film 24, the photoresist film may be stripped away.

Subsequently, the UBM pattern 70 may be formed on the exposed redistribution layer 30. A solder crack control part 50 that can control crack defects of a solder ball 60 may be formed on at least a portion of the UBM pattern 70. Specifically, after applying a photoresist film onto the UBM patter 70, the exposure and development processes may be performed sequentially to create a space where the solder crack control part 50 is to be formed, and after forming the solder crack control part 50 on the exposed UBM pattern 70, the solder crack control part 50 may be formed by removing the photoresist film.

Finally, the solder ball 60 may be formed on the exposed UBM pattern 70 and the solder crack control part 50, resulting in the semiconductor package 110 as shown in FIG. 14.

Here, the top surface level of the solder crack control part 50 may be formed relatively higher than the top surface level of the UBM pattern 70, and the solder crack control part 50 may be formed with a thickness twice or more the thickness of the UBM pattern 70 formed on the second insulating film 24.

When using the UBM pattern 70, the thickness of the solder crack control part 50 may be controlled by the thickness of the UBM pattern 70. There is no need to consider constraints on the thickness of the redistribution layer 30, and the thickness of the UBM pattern 70 may be formed to be 7 μm or more considering, for example, the Cu IMC layer, based on the top surface of the second insulating film 24. In this case, the thickness of the solder crack control part 50 may be formed to be 14 μm or more, which is twice the thickness of the UBM pattern 70.

As described above, applying the solder crack control part 50 improves the reliability of semiconductor packages 100 and 110 and may result in an increase in the bonding area with the solder ball by at least 10%, thereby enhancing adhesion.

In accordance with an embodiment of the present invention as described above, cracks in a pad may be minimized during attaching a solder ball, thereby improving solder bonding characteristics between various components and preventing an open phenomenon in a terminal. However, the above effects do not limit the scope of the present invention.

Although the present invention has been described with reference to the embodiments shown in the drawings, however, these are merely proposed for illustrative purposes, and those skilled in the art will appreciate that various modifications and other equivalent embodiments are possible. Therefore, the true and technical range of the present invention to be protected would be defined on the basis of technical spirit disclosed in the appended claims.

What is claimed is:

1. A method of fabricating a semiconductor package, the method comprising:
forming a first insulating film on a substrate which is at least partially provided with a semiconductor chip;
forming a redistribution layer on the first insulating film;
forming a solder crack control part, capable of controlling crack defects of a solder ball, on at least a portion of the redistribution layer;
forming a second insulating layer on the redistribution layer and at least a portion of the first insulating film to expose a portion of the redistribution layer and the solder crack control part; and
forming a solder ball on the redistribution layer exposed and the solder crack control part,
wherein a top surface level of the solder crack control part may be formed to be relatively higher than a top surface level of the second insulating film.

2. The method of claim 1, wherein the solder crack control part is formed with a thickness twice or more a thickness of the second insulating film formed on the redistribution layer.

3. The method of claim 1, wherein the forming of the redistribution layer comprises:
forming a redistribution seed layer on the first insulating film;
forming a space where the redistribution layer is to be formed by applying a photoresist film on the seed layer, followed by sequentially performing an exposure process and a development process;
forming the redistribution layer on the redistribution seed layer exposed; and
removing the photoresist film after forming the redistribution layer.

4. The method of claim 3, wherein the forming of the solder crack control part comprises:
forming a space where the solder crack control part is to be formed by applying a photoresist film on the redistribution layer, followed by sequentially performing an exposure process and a development process;
forming the solder crack control part on the exposed redistribution layer; and
removing the photoresist film after forming the solder crack control part.

5. The method of claim 3, further comprising, after removing the photoresist film, removing at least a portion of the exposed redistribution seed layer.

6. The method of claim 1, wherein the forming of the second insulating film comprises coating the second insulating film on the first insulating film exposed and at least a portion of the redistribution layer by using a mask.

7. The method of claim 1, wherein the forming of the second insulating film comprises:
forming a space where the second insulating film is to be formed by applying a photoresist film on the redistribution layer and at least a portion of the solder crack control part, followed by sequentially performing an exposure process and a development process;
forming the second insulating layer on the exposed first insulating film and redistribution layer; and
removing the photoresist film after forming the second insulating film.

8. A method of fabricating a semiconductor package, the method comprising:
forming a first insulating film on a substrate which is at least partially provided with a semiconductor chip;
forming a redistribution layer on the first insulating film;
forming a second insulating layer on the redistribution layer and the first insulating film except for a space where an under bump metal (UBM) pattern is to be formed in a portion of the redistribution layer;
forming the UBM pattern on the redistribution layer exposed;
forming a solder crack control part, capable of controlling crack defects of a solder ball, on at least a portion of the UBM; and
forming a solder ball on the UBM pattern exposed and the solder crack control part,
wherein a top surface level of the solder crack control part may be formed to be relatively higher than a top surface level of the UBM pattern.

9. The method of claim 8, wherein the solder crack control part is formed with a thickness twice or more a thickness of the UBM pattern formed on the second insulating film.

10. The method of claim 8, wherein the forming of the solder crack control part comprises:
forming a space where the solder crack control part is to be formed by applying a photoresist film on the redistribution layer, followed by sequentially performing an exposure process and a development process;
forming the solder crack control part on the exposed UBM pattern; and
removing the photoresist film after forming the solder crack control part.

11. The method of claim 8, wherein the forming of the redistribution layer comprises:
forming a redistribution seed layer on the first insulating film;
forming a space where the redistribution layer is to be formed by applying a photoresist film on the seed layer, followed by sequentially performing an exposure process and a development process;
forming the redistribution layer on the redistribution seed layer exposed;
removing the photoresist film after forming the redistribution layer; and
removing at least a portion of the redistribution seed layer exposed.

12. The method of claim 8, wherein the forming of the second insulating film comprises coating the second insulating film on the first insulating film exposed and at least a portion of the redistribution layer by using a mask.

13. The method of claim 9, wherein the forming of the second insulating film comprises:
forming a space where the second insulating film is to be formed by applying a photoresist film on the redistribution layer, followed by sequentially performing an exposure process and a development process;
forming the second insulating layer on the exposed first insulating film and redistribution layer; and
removing the photoresist film after forming the second insulating film.

14. A semiconductor package, which is a fan-out wafer-level semiconductor package, comprising:
a first insulating film formed on a substrate which is partially provided with a semiconductor chip;
a redistribution layer formed on the first insulating film;
a second insulating film formed on the redistribution layer and the first insulating film exposed;
a solder crack control part formed on the redistribution layer exposed; and
a solder ball formed on the exposed redistribution layer and the solder crack control part,
wherein a top surface level of the solder crack control part may be formed to be relatively higher than a top surface level of the second insulating film.

15. The semiconductor package of claim 14, wherein the solder crack control part is formed with a thickness twice or more a thickness of the second insulating film formed on the redistribution layer.

16. The semiconductor package of claim 14, further comprising:
an under bump metal (UBM) pattern interposed between the solder crack control part and the redistribution layer,
wherein the exposed redistribution layer is enclosed by the UBM pattern.

17. The semiconductor package of claim 15, wherein the solder ball is formed on the UBM pattern and the solder crack control part.

18. The semiconductor package of claim 15, wherein the solder crack control part is formed with a thickness twice or more a thickness of the UBM pattern formed on the second insulating film.

19. The semiconductor package of claim 14, wherein the solder crack control part is formed in one of the shapes of a cylinder, a donut, or a polygonal cylinder.
